(19) United States
(12) Patent Application Publication
(10) Pub. No.: US 2023/0128904 A1
(43) Pub. Date: Apr. 27, 2023

(54) DISPLAY DEVICE AND METHOD OF MANUFACTURING THE DISPLAY DEVICE

(71) Applicant: Samsung Display Co., LTD., Yongin-si (KR)

(72) Inventors: Young Gu KIM, Yongin-si (KR); Yun Hee PARK, Yongin-si (KR); Ji Yun PARK, Yongin-si (KR); Suk Kung CHEI, Yongin-si (KR); Kyung Seon TAK, Yongin-si (KR)

(73) Assignee: Samsung Display Co., LTD., Yongin-si (KR)

(21) Appl. No.: 17/751,025

(22) Filed: May 23, 2022

(30) Foreign Application Priority Data
Oct. 27, 2021 (KR) 10-2021-0144873

(51) Int. Cl. H01L 33/50; H01L 27/15; H01L 33/58; H01L 33/00

(52) U.S. Cl. CPC H01L 33/505; H01L 27/156; H01L 33/58; H01L 33/005; H01L 2933/0041

(57) ABSTRACT

A display device and a method of manufacturing the display device are provided. The display device includes pixels and a bank including an opening overlapping each of the pixels in a plan view, light emitting elements disposed in the pixels, a color conversion layer disposed on the light emitting elements in the opening of the bank, and an optical layer disposed on the color conversion layer in the opening of the bank. The optical layer includes an organic layer surrounding voids of the optical layer.

### CROSS-REFERENCE TO RELATED APPLICATION(S)

This application claims priority to and benefits of Korean Patent Application No. 10-2021-0144873 under 35 U.S.C. § 119 filed on Oct. 27, 2021 in the Korean Intellectual Property Office, the entire contents of which are incorporated herein by reference.

### BACKGROUND

### 1. Technical Field

The disclosure relates to a display device and a method of manufacturing the display device.

### 2. Description of the Related Art

Recently, interest in information display has been increasing. Accordingly, research and development on display devices are continuously being conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device including an optical layer having an ultra-low refractive index.

The objects of the disclosure are not limited to the above objects, and other objects will be clearly understood by those of ordinary skill in the art from the following description.

According to an embodiment, a display device may include pixels; a bank including an opening overlapping each of the pixels in a plan view; light emitting elements disposed in the pixels; a color conversion layer disposed on the light emitting elements in the opening of the bank; and an optical layer disposed on the color conversion layer in the opening of the bank, wherein the optical layer may include an organic layer surrounding voids of the optical layer.

The optical layer may have a refractive index of about 1.25 or less.

The optical layer may have a thickness in a range of 0.2 μm to about 3.0 μm.

The voids of the optical layer may have different diameters.

Each of the voids of the optical layer may have a diameter in a range of about 2 nm to about 150 nm.

The pixels may include first pixels, second pixels, and third pixels, and optical layers of the first pixels, the second pixels, and the third pixels may be separated from each other.

The display device may further include a first capping layer disposed between the color conversion layer and the optical layer.

The display device may further include a second capping layer overlapping the optical layer in a plan view.

The second capping layer may contact the first capping layer on the bank.

The light emitting elements may each include a first semiconductor layer; a second semiconductor layer disposed on the first semiconductor layer; and an active layer disposed between the first semiconductor layer and the second semiconductor layer.

According to an embodiment, a method of manufacturing a display device may include providing a bank including an opening overlapping light emitting elements of pixels in a plan view; providing a color conversion layer in the opening of the bank; providing an optical material layer including a void-forming material on the color conversion layer; and performing heat treatment on the optical material layer to volatilize the void-forming material to form an optical layer.

The method of manufacturing a display device may further include volatizing the void-forming material to form voids in the optical layer.

The heat treatment may be performed at about 200° C. or less.

A content of the void-forming material may be in a range of about 40 wt % to about 70 wt % based on a total weight of the optical material layer.

The voids of the optical layer may be formed to have different diameters.

Each of the voids of the optical layer may be formed to have a diameter in a range of about 2 nm to about 150 nm.

The optical layer may be formed to have a thickness in a range of about 0.2 μm to about 3.0 μm.

The optical material layer may be disposed in the opening of the bank.

The pixels may include first pixels, second pixels, and third pixels, and the optical material layer may be disposed separately in the first pixels, the second pixels, and the third pixels.

The optical material layer may be provided by inkjet printing.

Other embodiments are included in the detailed description and drawings.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a light emitting element according to an embodiment.

FIG. 2 is a schematic cross-sectional view illustrating a light emitting element according to an embodiment.

FIG. 3 is a schematic plan view illustrating a display device according to an embodiment.

FIG. 4 is a schematic diagram of an equivalent circuit of a pixel according to an embodiment.

FIG. 5 is a schematic plan view illustrating a pixel according to an embodiment.

FIG. 6 is a schematic cross-sectional view taken along line A-A′ of FIG. 5.

FIG. 7 is a schematic cross-sectional view illustrating first to third pixels according to an embodiment.

FIG. 8 is a schematic cross-sectional view illustrating an optical layer of FIG. 7.

FIGS. 9 to 15 are schematic cross-sectional views of step-by-step processes of a method of manufacturing a display device according to an embodiment.

### DETAILED DESCRIPTION OF THE EMBODIMENTS

Advantages and features of the disclosure, and methods of achieving them will be clarified with reference to embodiments described below in detail with reference to the accompanying drawings. However, the disclosure is not limited to the following embodiments and may be embodied in different various forms. The disclosure is not limited to the embodiments disclosed below, but will be implemented in various different forms. The embodiments are provided so that the disclosure is complete and are provided to fully inform those of ordinary skill in the art to which the disclosure pertains, the scope of the disclosure. The disclosure may be defined by the scope of the claims.

The terminology used herein is for the purpose of describing the embodiments and is not intended to limit the disclosure.

In the drawings, sizes, thicknesses, ratios, and dimensions of the elements may be exaggerated for ease of description and for clarity. Like numbers refer to like elements throughout.

The singular forms “a,” “an,” and “the” as used herein are intended to include the plural forms as well unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

In addition, the terms “connection” or “coupling” may refer to a physical and/or electrical connection or coupling inclusively. It may also refer generically to a direct or indirect connection or coupling and an integral or non-integral connection or coupling.

It will be understood that, when an element or a layer is referred to as being “on” another element or layer, it may be directly or indirectly on the other element or layer, for example, intervening elements or layers may be present therebetween. The same reference numerals refer to the same elements throughout the specification.

It will be understood that although “first,” “second,” etc. may be used herein to describe various elements, these elements should not be limited by these terms. These terms are only used to distinguish one element from another. Therefore, it is apparent that a first element described below may be a second element within the spirit and scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the disclosure will be described in detail with reference to the accompanying drawings.

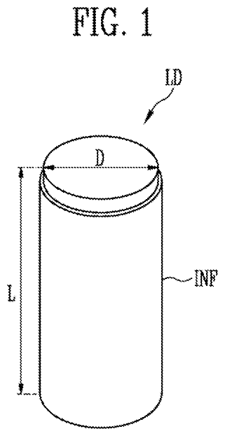

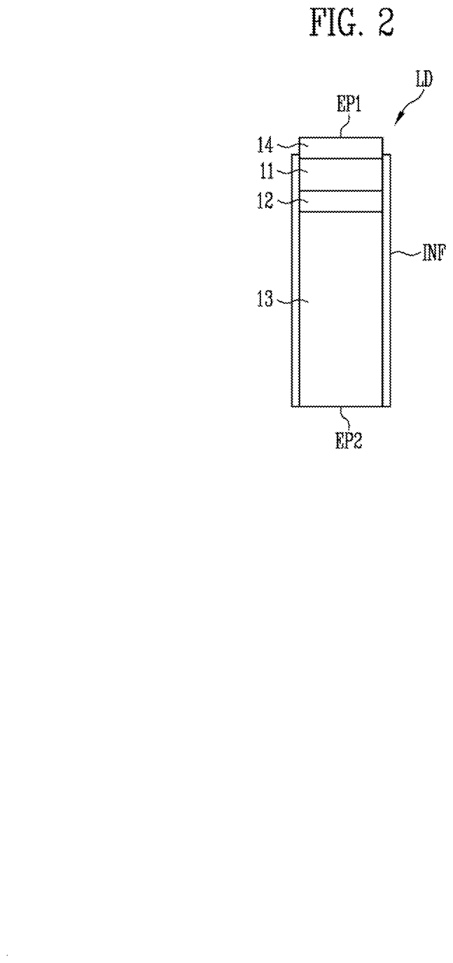

FIG. 1 is a schematic perspective view illustrating a light emitting element according to an embodiment. FIG. 2 is a schematic cross-sectional view illustrating the light emitting element according to an embodiment. Although a pillar-shaped light emitting element LD is illustrated in FIGS. 1 and 2, the type and/or shape of the light emitting element LD is not limited thereto. It is to be understood that the shapes disclosed herein may include shapes substantially identical or similar to the shapes.

Referring to FIGS. 1 and 2, the light emitting element LD may include a first semiconductor layer 11, an active layer 12, a second semiconductor layer 13, and/or an electrode layer 14.

The light emitting element LD may be formed in a pillar shape extending in one direction or a direction. The light emitting element LD may have a first end EP1 and a second end EP2. One of the first and second semiconductor layers 11 and 13 may be disposed on the first end EP1 of the light emitting element LD. The other of the first and second semiconductor layers 11 and 13 may be disposed on the second end EP2 of the light emitting element LD. For example, the first semiconductor layer 11 may be disposed on the first end EP1 of the light emitting element LD, and the second semiconductor layer 13 may be disposed on the second end EP2 of the light emitting element LD.

In an embodiment, the light emitting element LD may be a light emitting element manufactured in a pillar shape through an etching method or the like within the spirit and the scope of the disclosure. In this specification, the pillar shape encompasses a rod-like shape or a bar-like shape with an aspect ratio greater than 1, such as a cylinder or a polyprism, and the shape of the cross-section thereof is limited.

The light emitting element LD may have a size as small as a nanometer scale to a micrometer scale. As an example, each of the light emitting elements LD may have a diameter D (or width) and/or a length L in a range of a nanometer scale to a micrometer scale. However, the size of the light emitting element LD is not limited thereto, and the size of the light emitting element LD may vary depending on design conditions of various devices, for example, display devices, in which a light emitting device using the light emitting element LD is used as a light source.

The first semiconductor layer 11 may be a semiconductor layer of a first conductivity type. For example, the first semiconductor layer 11 may include a p-type semiconductor layer. For example, the first semiconductor layer 11 may include at least one semiconductor material selected from InAlGaN, GaN, AlGaN, InGaN, or AlN, and may include a p-type semiconductor layer doped with a first conductivity type dopant such as Mg. However, a material constituting the first semiconductor layer 11 is not limited thereto, and various other materials may be used to form the first semiconductor layer 11.

The active layer 12 may be disposed between the first semiconductor layer 11 and the second semiconductor layer 13. The active layer 12 may include one of a single well structure, a multi-well structure, a single quantum well structure, a multi quantum well (MQW) structure, a quantum dot structure, or a quantum wire structure, but the disclosure is not necessarily limited thereto.

The active layer 12 may include GaN, InGaN, InAlGaN, AlGaN, or AlN, and various materials may constitute the active layer 12.

In case that a voltage equal to or greater than a threshold voltage is applied to both ends of the light emitting element LD, the light emitting element LD emits light while electron-hole pairs are recombined in the active layer 12. By controlling the light emission of the light emitting element LD using this principle, the light emitting element LD can be used as the light source of various light emitting devices including pixels of a display device.

The second semiconductor layer 13 may be disposed on the active layer 12, and may include a semiconductor layer of a different type from that of the first semiconductor layer 11. The second semiconductor layer 13 may include an n-type semiconductor layer. For example, the second semiconductor layer 13 may include one semiconductor material selected from InAlGaN, GaN, AlGaN, InGaN, or AlN, and may include an n-type semiconductor layer doped with a second conductivity type dopant such as Si, Ge, or Sn. However, a material constituting the second semiconductor layer 13 is not limited thereto, and various other materials may be used to form the second semiconductor layer 13.

The electrode layer 14 may be disposed on the first end EP1 and/or the second end EP2 of the light emitting element LD. FIG. 2 illustrates a case in which the electrode layer 14 is formed on the first semiconductor layer 11, but the disclosure is not necessarily limited thereto. For example, a separate electrode layer may be further disposed on the second semiconductor layer 13.

The electrode layer 14 may include a transparent metal or a transparent metal oxide. For example, the electrode layer 14 may include at least one of indium tin oxide (ITO), indium zinc oxide (IZO), and zinc tin oxide (ZTO), but the disclosure is not necessarily limited thereto. As such, in case that the electrode layer 14 may include a transparent metal or a transparent metal oxide, light generated in the active layer 12 of the light emitting element LD may be emitted to the outside of the light emitting element LD through the electrode layer 14.

An insulating film INF may be provided on the surface of the light emitting element LD. The insulating film INF may be disposed on or directly disposed on the surfaces of the first semiconductor layer 11, the active layer 12, the second semiconductor layer 13, and/or the electrode layer 14. The insulating film INF may expose the first and second ends EP1 and EP2 of the light emitting element LD having different polarities. In an embodiment, the insulating film INF may expose side portions of the electrode layer 14 and/or the second semiconductor layer 13 adjacent to the first and second ends EP1 and EP2 of the light emitting element LD.

The insulating film INF may prevent an electrical short that may occur in case that the active layer 12 comes into contact with a conductive material other than the first and second semiconductor layers 11 and 13. The insulating film INF may minimize surface defects of the light emitting element LD, thereby improving lifespan and luminescence efficiency of the light emitting elements LD.

The insulating film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). For example, the insulating film INF may include a double layer, and the respective layers constituting the double layer may include different materials. For example, the insulating film INF may include a double layer including aluminum oxide (AlOₓ) and silicon oxide (SiOₓ), but the disclosure is not necessarily limited thereto. In an embodiment, the insulating film INF may be omitted.

The light emitting device including the light emitting element LD described above may be used in various types of devices requiring a light source, including a display device. For example, the light emitting elements LD may be disposed in each pixel of the display panel, and the light emitting elements LD may be used as a light source of each pixel. However, the field of application of the light emitting element LD is not limited to the above-described example. For example, the light emitting element LD may also be used in other types of devices that require a light source, such as a lighting device.

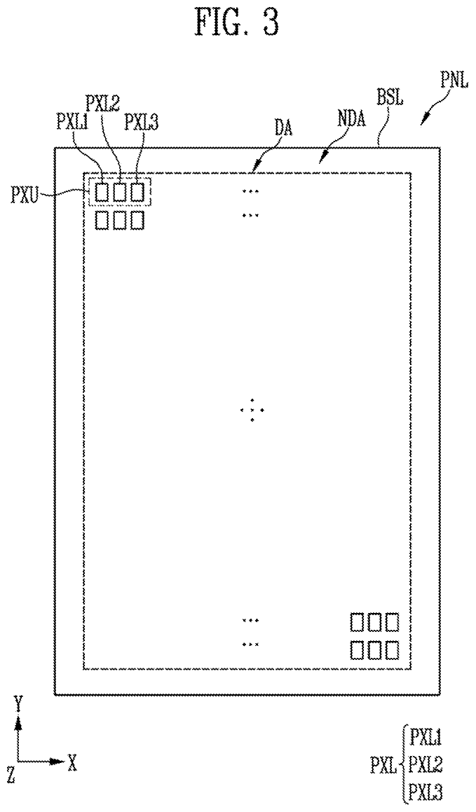

FIG. 3 is a schematic plan view illustrating a display device according to an embodiment.

FIG. 3 illustrates a display device, by way of example, a display panel PNL provided in the display device, as an example of an electronic device that can use the light emitting element LD described in the embodiments of FIGS. 1 and 2 as the light source.

For convenience of description, the structure of the display panel PNL is briefly illustrated focusing on a display area DA in FIG. 3. However, according to an embodiment, at least one driving circuit part (for example, at least one of a scan driver and a data driver), wires, and/or pads (not illustrated) may be further disposed on the display panel PNL.

Referring to FIG. 3, the display panel PNL and a base layer BSL for forming the display panel PNL may include a display area DA for displaying an image and a non-display area NDA excluding the display area DA. The display area DA may constitute a screen on which an image is displayed, and the non-display area NDA may be an area other than the display area DA.

A pixel unit PXU may be disposed in the display area DA. The pixel unit PXU may include a first pixel PXL1, a second pixel PXL2, and/or a third pixel PXL3. Hereinafter, at least one of the first pixel PXL1, the second pixel PXL2, and the third pixel PXL3 may be referred to as a “pixel PXL”, or two or more types of pixels may be collectively referred to as “pixels PXL”.

The pixels PXL may be regularly arranged or disposed according to a stripe or PENTILE™ arrangement structure. However, the arrangement structure of the pixels PXL is not limited thereto, and the pixels PXL may be arranged or disposed in the display area DA in various structures and/or methods.

According to an embodiment, two or more types of pixels PXL emitting light of different colors may be disposed in the display area DA. For example, first pixels PXL1 emitting light of a first color, second pixels PXL2 emitting light of a second color, and third pixels PXL3 emitting light of a third color may be arranged or disposed in the display area DA. At least one of the first to third pixels PXL1, PXL2, and PXL3 disposed adjacent to each other may constitute one pixel unit PXU that emits light of various colors. For example, each of the first to third pixels PXL1, PXL2, and PXL3 may be a pixel emitting light of a color. According to an embodiment, the first pixel PXL1 may be a red pixel emitting red light, the second pixel PXL2 may be a green pixel emitting green light, and the third pixel PXL3 may be a blue pixel emitting blue light, but the disclosure is not limited thereto.

In an embodiment, the first pixel PXL1, the second pixel PXL2, and the third pixel PXL3 include light emitting elements emitting light of a same color as each other. However, by including color conversion layers and/or color filter layers of different colors disposed on each light emitting element, light of the first color, light of the second color, and light of the third color may be emitted, respectively. In an embodiment, the first pixel PXL1, the second pixel PXL2, and the third pixel PXL3 include a light emitting element of a first color, a light emitting element of a second color, and a light emitting element of a third color to emit light of the first color, light of the second color, and light of the third color, respectively. However, the color, type, and/or number of pixels PXL constituting each pixel unit PXU is not particularly limited. For example, the color of the light emitted by each pixel PXL may be variously changed.

The pixel PXL may include at least one light source driven by a control signal (for example, a scan signal and a data signal) and/or a power (for example, a first power supply and a second power supply). In an embodiment, the light source may include, for example, ultra-small pillar-shaped light emitting elements LD having a size as small as a nanometer scale to a micrometer scale as at least one light emitting element LD according to one of the embodiments of FIGS. 1 and 2. However, the disclosure is not necessarily limited thereto, and various types of light emitting elements LD may be used as the light source of the pixel PXL.

In an embodiment, each pixel PXL may be an active pixel. However, the types, structures, and/or driving methods of the pixels PXL applicable to the display device are not particularly limited. For example, each pixel PXL may be a pixel of a passive or active type light emitting display device having various structures and/or driving methods.

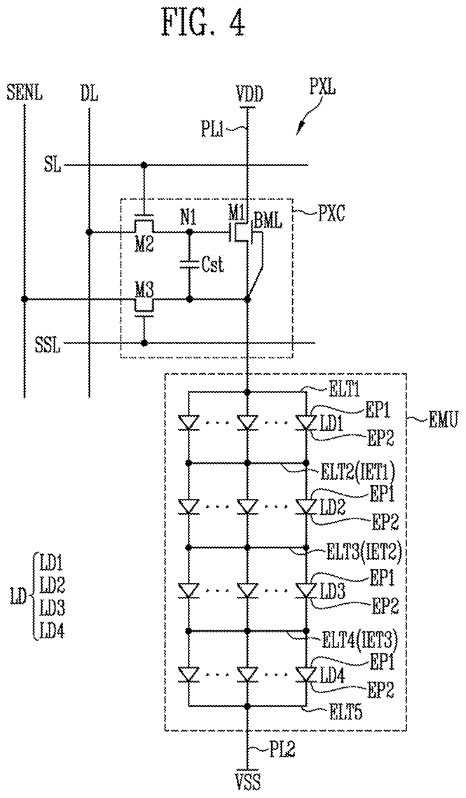

FIG. 4 is a schematic diagram of an equivalent circuit of a pixel according to an embodiment.

According to an embodiment, the pixel PXL illustrated in FIG. 4 may be one of the first pixel PXL1, the second pixel PXL2, and the third pixel PXL3 provided in the display panel PNL of FIG. 3. The first pixel PXL1, the second pixel PXL2, and the third pixel PXL3 may have substantially the identical or similar structure to each other.

Referring to FIG. 4, each pixel PXL may further include a light emitting unit EMU for generating light having a luminance corresponding to a data signal, and a pixel circuit PXC for driving the light emitting unit EMU.

The pixel circuit PXC may be connected between the first power supply VDD and the light emitting unit EMU. The pixel circuit PXC may be connected to a scan line SL and a data line DL of the corresponding pixel PXL, and may control the operation of the light emitting unit EMU in response to the scan signal and the data signal supplied from the scan line SL and the data line DL. The pixel circuit PXC may be further selectively connected to a sensing signal line SSL and a sensing line SENL.

The pixel circuit PXC may include at least one transistor and a capacitor. For example, the pixel circuit PXC may include a first transistor M1, a second transistor M2, a third transistor M3, and a storage capacitor Cst.

The first transistor M1 may be connected between the first power supply VDD and a first connection electrode ELT1. A gate electrode of the first transistor M1 may be connected to a first node N1. The first transistor M1 may control a driving current supplied to the light emitting unit EMU in response to a voltage of the first node N1. For example, the first transistor M1 may be a driving transistor for controlling the driving current of the pixel PXL.

In an embodiment, the first transistor M1 may optionally include a lower conductive layer BML (also referred to as a “lower electrode”, a “back gate electrode”, or a “lower light blocking layer”). The gate electrode of the first transistor M1 and the lower conductive layer BML may overlap each other with an insulating layer disposed therebetween. In an embodiment, the lower conductive layer BML may be connected to one electrode of the first transistor M1, for example, a source electrode or a drain electrode.

In case that the first transistor M1 may include the lower conductive layer BML, a back-biasing technology (or a sync technology) may be applied in case that the pixel PXL is driven. For example, a back-biasing voltage is applied to the lower conductive layer BML of the first transistor M1 to shift a threshold voltage of the first transistor M1 in a negative or positive direction. For example, by connecting the lower conductive layer BML to the source electrode of the first transistor M1 and applying the source-sink technology, the threshold voltage of the first transistor M1 may be shifted in a negative or positive direction. In case that the lower conductive layer BML is disposed under or below the semiconductor pattern constituting the channel of the first transistor M1, the lower conductive layer BML may serve as a light blocking pattern to stabilize operating characteristics of the first transistor M1. However, the function and/or utilization method of the lower conductive layer BML is not limited thereto.

The second transistor M2 may be connected between the data line DL and the first node N1. The gate electrode of the second transistor M2 may be connected to the scan line SL. The second transistor M2 may be turned on in case that a scan signal of a gate-on voltage (for example, a high level voltage) is supplied from the scan line SL, and may connect the data line DL to the first node N1.

For each frame period, a data signal of the corresponding frame may be supplied to the data line DL, and the data signal may be transmitted to the first node N1 through the second transistor M2 that is turned on during a period in which the scan signal of the gate-on voltage is supplied. For example, the second transistor M2 may be a switching transistor for transmitting each data signal to the inside of the pixel PXL.

One electrode of the storage capacitor Cst may be connected to the first node N1, and the other electrode of the storage capacitor Cst may be connected to the second electrode of the first transistor M1. The storage capacitor Cst may be charged with a voltage corresponding to the data signal supplied to the first node N1 during each frame period.

The third transistor M3 may be connected between the first connection electrode ELT1 (or the second electrode of the first transistor M1) and the sensing line SENL. A gate electrode of the third transistor M3 may be connected to the sensing signal line SSL. The third transistor M3 may transmit a voltage value applied to the first connection electrode ELT1 to the sensing line SENL according to the sensing signal supplied to the sensing signal line SSL. The voltage value transmitted through the sensing line SENL may be provided to an external circuit (for example, a timing controller), and the external circuit may extract characteristic information (for example, the threshold voltage of the first transistor M1) of each pixel PXL based on the provided voltage value. The extracted characteristic information may be used to convert image data so that characteristic deviation between the pixels PXL is compensated.

Although all of the transistors included in the pixel circuit PXC are illustrated as n-type transistors in FIG. 4, the disclosure is not necessarily limited thereto. For example, at least one of the first, second, and third transistors M1, M2, and M3 may be changed to a p-type transistor.

The structure and driving method of the pixel PXL may be variously changed. For example, the pixel circuit PXC may include pixel circuits having various structures and/or driving methods in addition to an embodiment illustrated in FIG. 4.

For example, the pixel circuit PXC may not include the third transistor M3. The pixel circuit PXC may further include other circuit elements, such as a compensation transistor for compensating for the threshold voltage of the first transistor M1, an initialization transistor for initializing the voltage of the first node N1 and/or the first connection electrode ELT1, an emission control transistor for controlling a period in which the driving current is supplied to the light emitting unit EMU, and/or a boosting capacitor for boosting the voltage of the first node N1.

The light emitting unit EMU may include at least one light emitting element LD, for example, light emitting elements LD, connected between the first power supply VDD and the second power supply VSS.

For example, the light emitting unit EMU may include a first connection electrode ELT1 connected to the first power supply VDD through the pixel circuit PXC and the first power line PL1, a fifth connection electrode ELT5 connected to the second power supply VSS through the second power line PL2, and light emitting elements LD connected between the first and fifth connection electrodes ELT1 and ELT5.

The first power supply VDD and the second power supply VSS may have different potentials so that the light emitting elements LD emit light. For example, the first power supply VDD may be set as a high potential power supply, and the second power supply VSS may be set as a low potential power supply.

In an embodiment, the light emitting unit EMU may include at least one series stage. Each series stage may include a pair of electrodes (for example, two electrodes) and at least one light emitting element LD connected in a forward direction between the pair of electrodes. The number of series stages constituting the light emitting unit EMU and the number of light emitting elements LD constituting each series stage are not particularly limited. For example, the number of light emitting elements LD constituting each series stage may be identical to or different from each other, and the number of light emitting elements LD is not particularly limited.

For example, the light emitting unit EMU may include a first series stage including at least one first light emitting element LD1, a second series stage including at least one second light emitting element LD2, a third series stage including at least one third light emitting element LD3, and a fourth series stage including at least one fourth light emitting element LD4.

The first series stage may include the first connection electrode ELT1, the second connection electrode ELT2, and at least one first light emitting element LD1 connected between the first and second connection electrodes ELT1 and ELT2. Each of the first light emitting elements LD1 may be connected in a forward direction between the first and second connection electrodes ELT1 and ELT2. For example, the first end EP1 of the first light emitting element LD1 may be connected to the first connection electrode ELT1, and the second end EP2 of the first light emitting element LD1 may be connected to the second connection electrode ELT2.

The second series stage may include the second connection electrode ELT2, the third connection electrode ELT3, and at least one second light emitting element LD2 connected between the second and third connection electrodes ELT2 and ELT3. Each of the second light emitting elements LD2 may be connected in a forward direction between the second and third connection electrodes ELT2 and ELT3. For example, the first end EP1 of the second light emitting element LD2 may be connected to the second connection electrode ELT2, and the second end EP2 of the second light emitting element LD2 may be connected to the third connection electrode ELT3.

The third series stage may include the third connection electrode ELT3, the fourth connection electrode ELT4, and at least one third light emitting element LD3 connected between the third and fourth connection electrodes ELT3 and ELT4. Each of the third light emitting elements LD3 may be connected in a forward direction between the third and fourth connection electrodes ELT3 and ELT4. For example, the first end EP1 of the third light emitting element LD3 may be connected to the third connection electrode ELT3, and the second end EP2 of the third light emitting element LD3 may be connected to the fourth connection electrode ELT4.

The fourth series stage may include the fourth connection electrode ELT4, the fifth connection electrode ELT5, and at least one fourth light emitting element LD4 connected between the fourth and fifth connection electrodes ELT4 and ELT5. Each of the fourth light emitting elements LD4 may be connected in a forward direction between the fourth and fifth connection electrodes ELT4 and ELT5. For example, the first end EP1 of the fourth light emitting element LD4 may be connected to the fourth connection electrode ELT4, and the second end EP2 of the fourth light emitting element LD4 may be connected to the fifth connection electrode ELT5.

The first electrode of the light emitting unit EMU, for example, the first connection electrode ELT1 may be an anode electrode of the light emitting unit EMU. The last electrode of the light emitting unit EMU, for example, the fifth connection electrode ELT5 may be a cathode electrode of the light emitting unit EMU.

The remaining electrodes of the light emitting unit EMU, for example, the second connection electrode ELT2, the third connection electrode ELT3, and/or the fourth connection electrode ELT4 may constitute intermediate electrodes. For example, the second connection electrode ELT2 may constitute the first intermediate electrode IET1, the third connection electrode ELT3 may constitute the second intermediate electrode IET2, and the fourth connection electrode ELT4 may constitute the third intermediate electrode IET3.

In case that the light emitting elements LD are connected in a series/parallel structure, power efficiency may be improved compared to a case where the same number of light emitting elements LD are connected only in parallel. In the pixel PXL in which the light emitting elements LD are connected in a series/parallel structure, even if a short defect occurs in some or a number of series terminals, a luminance can be expressed through the light emitting elements LD of the remaining series stage, thereby reducing the possibility of defective dark spots in the pixel PXL. However, the disclosure is not necessarily limited thereto, and the light emitting elements LD may be connected only in series to form the light emitting unit EMU, or may be connected only in parallel to form the light emitting unit EMU.

The light emitting elements LD may include a first end EP1 (for example, a p-type end) connected to the first power supply VDD via at least one electrode (for example, the first connection electrode ELT1), the pixel circuit PXC, and/or the first power supply line PL1, and a second end EP2 (for example, an n-type end) connected to the second power supply VSS via at least one other electrode (for example, the fifth connection electrode ELT5) and the second power line PL2. For example, the light emitting elements LD may be connected in a forward direction between the first power supply VDD and the second power supply VSS. The light emitting elements LD connected in a forward direction may constitute effective light supplies of the light emitting unit EMU.

In case that the driving current is supplied through the pixel circuit PXC, the light emitting elements LD may emit light with a luminance corresponding to the driving current. For example, during each frame period, the pixel circuit PXC may supply a driving current corresponding to a gray scale value to be expressed in the corresponding frame to the light emitting unit EMU. Therefore, while the light emitting elements LD emit light with a luminance corresponding to the driving current, the light emitting unit EMU may express the luminance corresponding to the driving current.

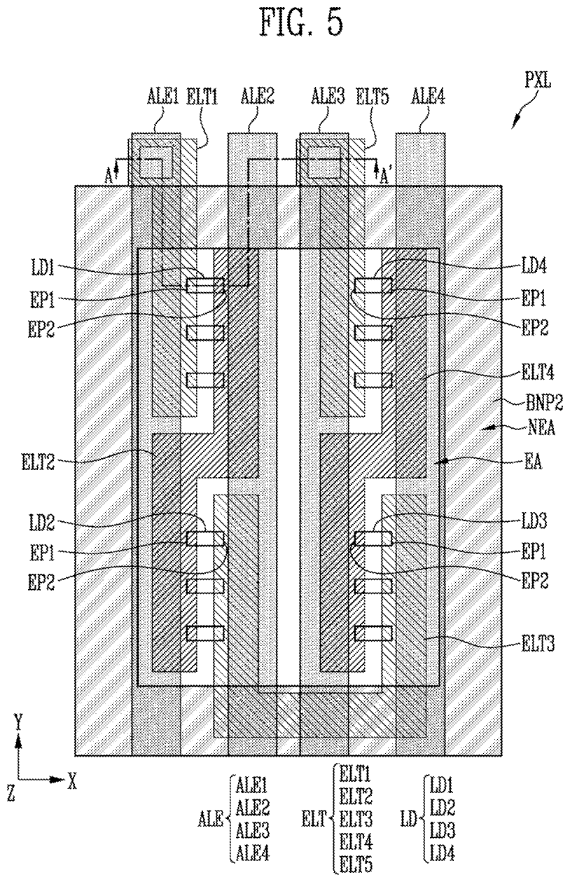

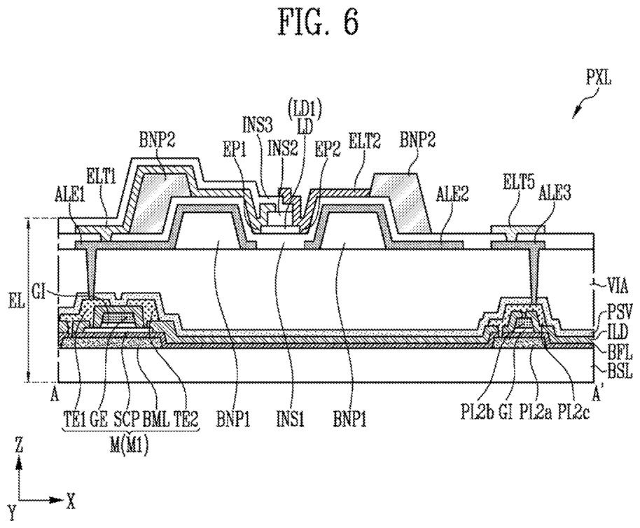

FIG. 5 is a schematic plan view illustrating the pixel according to an embodiment. FIG. 6 is a schematic cross-sectional view taken along line A-A′ of FIG. 5.

As an example, FIG. 5 may illustrate one of the first to third pixels PXL1, PXL2, and PXL3 constituting the pixel unit PXU of FIG. 3, and the first to third pixels PXL1, PXL2, and PXL3 may have the substantially identical or similar structure to each other. Also, FIG. 5 discloses an embodiment in which each pixel PXL may include light emitting elements LD disposed in four series stages as illustrated in FIG. 4, but the number of serial stages of each pixel PXL may be variously changed according to an embodiment.

Hereinafter, one or more of the first to fourth light emitting elements LD1, LD2, LD3, and LD4 may be referred to as a “light emitting element LD”, or two or more types of light emitting elements may be referred to as “light emitting elements LD”. At least one of the electrodes including the first to fourth electrodes ALE1, ALE2, ALE3, ALE4 may be referred to as an “electrode ALE” or “electrodes ALE”, and at least one of the electrodes including the first to fifth connection electrodes ELT1, ELT2, ELT3, ELT4, and ELT5 may be referred to a “connection electrode ELT” or “connection electrodes ELT”.

Referring to FIG. 5, each pixel PXL may include an emission area EA and a non-emission area NEA. The emission area EA may be an area that emits light, including the light emitting elements LD. The non-emission area NEA may be disposed to surround the emission area EA. The non-emission area NEA may be an area in which a second bank pattern BNP2 surrounding the emission area EA is provided.

Each of the pixels PXL may include electrodes ALE, light emitting elements LD, and/or connection electrodes ELT. The electrodes ALE may be provided in at least the emission area EA. The electrodes ALE may extend in the second direction (Y-axis direction) and may be apart from each other in the first direction (X-axis direction). The electrodes ALE may extend from the emission area EA to the non-emission area NEA. For example, the first to fourth electrodes ALE1, ALE2, ALE3, and ALE4 may extend in the second direction (Y-axis direction) and may be sequentially disposed while being apart from each other in the first direction (X-axis direction).

Some or a number of electrodes ALE may be connected to a pixel circuit (PXC of FIG. 4) and/or a power line through a contact hole. For example, the first electrode ALE1 may be connected to the pixel circuit PXC and/or the first power line PL1 through a contact hole, and the third electrode ALE3 may be connected to the second power line PL2 through a contact hole.

In an embodiment, some or a number of electrodes ALE may be electrically connected to some or a number of connection electrodes ELT through a contact hole. For example, the first electrode ALE1 may be electrically connected to the first connection electrode ELT1 through a contact hole, and the third electrode ALE3 may be electrically connected to the fifth connection electrode ELT5 through a contact hole.

A pair of electrodes ALE adjacent to each other may receive different signals in an alignment step of the light emitting elements LD. For example, in case that the first to fourth electrodes ALE1, ALE2, ALE3, and ALE4 are sequentially arranged or disposed in the first direction (X-axis direction) in the emission area EA, the first and second electrodes ALE1 and ALE2 may form a pair to receive different alignment signals, and the third and fourth electrodes ALE3 and ALE4 may form a pair to receive different alignment signals.

In an embodiment, the second and third electrodes ALE2 and ALE3 may receive the same signal in the alignment step of the light emitting elements LD. FIG. 5 illustrates that the second and third electrodes ALE2 and ALE3 are separated, but the second and third electrodes ALE2 and ALE3 may be integrally or non-integrally connected to each other in the alignment step of the light emitting elements LD.

In an embodiment, first bank patterns (BNP1 of FIG. 6) may be disposed under or below the electrodes ALE. The first bank patterns BNP1 may be provided in at least the emission area EA. The first bank patterns BNP1 may extend in the second direction (Y-axis direction) and may be apart from each other in the first direction (X-axis direction).

As the first bank patterns BNP1 are provided under or below one region or a region of each of the electrodes ALE, one area or an area of each of the electrodes ALE in the region where the first bank patterns BNP1 are formed may protrude in the upper direction of the pixel PXL, for example, in the third direction (Z-axis direction). In case that the first bank patterns BNP1 and/or the electrodes ALE include a reflective material, a reflective wall structure may be formed around the light emitting elements LD. Therefore, light emitted from the light emitting elements LD may be emitted in an upper direction of the pixel PXL (for example, the front direction of the display panel PNL including a viewing angle range), thereby improving light output efficiency of the display panel PNL.

Each of the light emitting elements LD may be aligned between the pair of electrodes ALE in the emission area EA. Also, the light emitting elements LD may be electrically connected between the pair of connection electrodes ELT.

The first light emitting element LD1 may be aligned between the first and second electrodes ALE1 and ALE2. The first light emitting element LD1 may be electrically connected between the first and second connection electrodes ELT1 and ELT2. For example, the first light emitting element LD1 may be aligned with the first region (for example, the upper region) of the first and second electrodes ALE1 and ALE2, the first end EP1 of the first light emitting element LD1 may be electrically connected to the first connection electrode ELT1, and the second end EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the first and second connection electrodes ELT2 and ELT3. For example, the second light emitting element LD2 may be aligned with the second region (for example, the lower region) of the first and second electrodes ALE1 and ALE2, the first end EP1 of the second light emitting element LD2 may be electrically connected to the second connection electrode ELT2, and the second end EP2 of the second light emitting element LD2 may be electrically connected to the second connection electrode ELT3.

The third light emitting element LD3 may be aligned between the third and fourth electrodes ALE3 and ALE4. The third light emitting element LD3 may be electrically connected between the third and fourth connection electrodes ELT3 and ELT4. For example, the third light emitting element LD3 may be aligned with the second region (for example, the lower region) of the third and fourth electrodes ALE3 and ALE4, the first end EP1 of the third light emitting element LD3 may be electrically connected to the third connection electrode ELT3, and the second end EP2 of the third light emitting element LD3 may be electrically connected to the fourth connection electrode ELT4.

The fourth light emitting element LD4 may be aligned between the third and fourth electrodes ALE3 and ALE4. The fourth light emitting element LD4 may be electrically connected between the fourth and fifth connection electrodes ELT4 and ELT5. For example, the fourth light emitting element LD4 may be aligned with the first region (for example, the upper region) of the third and fourth electrodes ALE3 and ALE4, the first end EP1 of the fourth light emitting element LD4 may be electrically connected to the fourth connection electrode ELT4, and the second end EP2 of the fourth light emitting element LD4 may be electrically connected to the fifth connection electrode ELT5.

For example, the first light emitting element LD1 may be positioned in the upper left region of the emission area EA, and the second light emitting element LD2 may be positioned in the lower left region of the emission area EA. The third light emitting element LD3 may be positioned in the lower right region of the emission area EA, and the fourth light emitting element LD4 may be positioned in the upper right region of the emission area EA. However, the arrangement and/or connection structure of the light emitting elements LD may be variously changed according to the structure of the light emitting unit EMU and/or the number of series stages.

Each of the connection electrodes ELT may be provided in at least the emission area EA and may be disposed to overlap at least one electrode ALE and/or the light emitting element LD. For example, the connection electrode ELT may be formed on the electrodes ALE and/or the light emitting elements LD to overlap the electrodes ALE and/or the light emitting elements LD, and may be electrically connected to the light emitting elements LD.

The first connection electrode ELT1 may be disposed on the first region (for example, the upper region) of the first electrode ALE1 and the first ends EP1 of the first light emitting elements LD1, and may be electrically connected to the first ends EP1 of the first light emitting elements LD1.

The second connection electrode ELT2 may be disposed on the first region (for example, the upper region) of the second electrode ALE2 and the second ends EP2 of the first light emitting elements LD1, and may be electrically connected to the second ends EP2 of the first light emitting elements LD1. The second connection electrode ELT2 may be disposed on the second region (for example, the lower region) of the first electrode ALE1 and the first ends EP1 of the second light emitting elements LD2, and may be electrically connected to the first ends EP1 of the second light emitting elements LD2. For example, the second connection electrode ELT2 may be electrically connected to the second ends EP2 of the first light emitting elements LD1 and the first ends EP1 of the second light emitting elements LD2 in the emission area EA. The second connection electrode ELT2 may have a curved shape. For example, the second connection electrode ELT2 may have a bent or curved structure at the boundary between the region in which at least one first light emitting element LD1 is arranged or disposed and the region in which at least one second light emitting element LD2 is arranged or disposed.

The third connection electrode ELT3 may be disposed on the second region (for example, the lower region) of the second electrode ALE2 and the second ends EP2 of the second light emitting elements LD2, and may be electrically connected to the second ends EP2 of the second light emitting elements LD2. The third connection electrode ELT3 may be disposed on the second region (for example, the lower region) of the fourth electrode ALE4 and the first ends EP1 of the third light emitting elements LD3, and may be electrically connected to the first ends EP1 of the third light emitting elements LD3. For example, the third connection electrode ELT3 may be electrically connected to the second ends EP2 of the second light emitting elements LD2 and the first ends EP1 of the third light emitting elements LD3 in the emission area EA. The third connection electrode ELT3 may have a curved shape. For example, the third connection electrode ELT3 may have a bent or curved structure at the boundary between the region in which at least one second light emitting element LD2 is arranged or disposed and the region in which at least one third light emitting element LD3 is arranged or disposed.

The fourth connection electrode ELT4 may be disposed on the second region (for example, the lower region) of the third electrode ALE3 and the second ends EP2 of the third light emitting elements LD3, and may be electrically connected to the second ends EP2 of the third light emitting elements LD3. The fourth connection electrode ELT4 may be disposed on the first region (for example, the upper region) of the fourth electrode ALE4 and the first ends EP1 of the fourth light emitting elements LD4, and may be electrically connected to the first ends EP1 of the fourth light emitting elements LD4. For example, the fourth connection electrode ELT4 may be electrically connected to the second ends EP2 of the third light emitting elements LD3 and the first ends EP1 of the fourth light emitting elements LD4 in the emission area EA. The fourth connection electrode ELT4 may have a curved shape. For example, the fourth connection electrode ELT4 may have a bent or curved structure at the boundary between the region in which at least one third light emitting element LD3 is arranged or disposed and the region in which at least one fourth light emitting element LD4 is arranged or disposed.

The fifth connection electrode ELT5 may be disposed on the first region (for example, the upper region) of the third electrode ALE3 and the second ends EP2 of the fourth light emitting elements LD4, and may be electrically connected to the second ends EP2 of the fourth light emitting elements LD4.

In the above-described manner, the light emitting elements LD arranged or disposed between the electrodes ALE may be connected in a desired shape by using the connection electrodes ELT. For example, the first light emitting elements LD1, the second light emitting elements LD2, the third light emitting elements LD3, and the fourth light emitting elements LD4 are sequentially connected in series by using the connection electrodes ELT.

Hereinafter, a cross-sectional structure of each pixel PXL will be described in detail with reference to FIG. 6, centering on the light emitting element LD. FIG. 6 illustrates the light emitting element layer EL of the pixel PXL. FIG. 6 illustrates the first transistor M1 among various circuit elements constituting the pixel circuit (PXC in FIG. 4). In case that there is no need to separately describe the first to third transistors M1, M2, and M3, they will be collectively referred to as “transistor M”. As an example, the structure and/or the position of each layer of the transistors M is not limited to an embodiment illustrated in FIG. 6, and may be variously changed according to an embodiment.

Referring to FIG. 6, the light emitting element layer EL of the pixels PXL according to an embodiment may include circuit elements including transistors M disposed on a base layer BSL and various wirings connected thereto. Electrodes ALE, light emitting elements LD, and/or connection electrodes ELT constituting the light emitting unit EMU may be disposed on the circuit elements.

The base layer BSL constitutes the base member and may be a rigid or flexible substrate or film. For example, the base layer BSL may be a rigid substrate including glass or tempered glass, a flexible substrate (or thin film) including plastic or metal, or at least one insulating layer. The material and/or physical properties of the base layer BSL are not particularly limited. In an embodiment, the base layer BSL may be substantially transparent. Here, the term “substantially transparent” may mean that light can be transmitted with a transmittance or higher. In an embodiment, the base layer BSL may be translucent or opaque. The base layer BSL may include a reflective material according to an embodiment.

A lower conductive layer BML and a first power conductive layer PL2a may be disposed on the base layer BSL. The lower conductive layer BML and the first power conductive layer PL2a may be disposed on a same layer. For example, the lower conductive layer BML and the first power conductive layer PL2a may be simultaneously formed in a same process, but the disclosure is not necessarily limited thereto. The first power conductive layer PL2a may constitute the second power supply line PL2 described with reference to FIG. 4 or the like within the spirit and the scope of the disclosure.

The lower conductive layer BML and the first power conductive layer PL2a may include a single layer or multiple layers including molybdenum (Mo), copper (Cu), aluminum (Al), chromium (Cr), gold (Au), titanium (Ti), and nickel (Ni), neodymium (Nd), indium (In), tin (Sn), and oxides or alloys thereof.

A buffer layer BFL may be disposed on the lower conductive layer BML and the first power conductive layer PL2a. The buffer layer BFL may prevent impurities from diffusing into the circuit element. The buffer layer BFL may be a single layer, but may also include at least a double layer or more. In case that the buffer layer BFL is formed as multiple layers, each layer may include a same material or a similar material or may include different materials.

A semiconductor pattern SCP may be disposed on the buffer layer BFL. For example, the semiconductor pattern SCP may include a first region in contact with the first transistor electrode TE1, a second region in contact with the second transistor electrode TE2, and a channel region between the first and second regions. According to an embodiment, one of the first and second regions may be a source region and the other thereof may be a drain region.

In an embodiment, the semiconductor pattern SCP may include polysilicon, amorphous silicon, oxide semiconductor, or the like within the spirit and the scope of the disclosure. The channel region of the semiconductor pattern SCP may be an intrinsic semiconductor as a semiconductor pattern not doped with impurities, and each of the first and second regions of the semiconductor pattern SCP may be a semiconductor doped with an impurity.

A gate insulating layer GI may be disposed on the buffer layer BFL and the semiconductor pattern SCP. For example, the gate insulating layer GI may be disposed between the semiconductor pattern SCP and the gate electrode GE. The gate insulating layer GI may be disposed between the buffer layer BFL and the second power conductive layer PL2b. The gate insulating layer GI may include a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The gate electrode GE of the transistor M and the second power conductive layer PL2b may be disposed on the gate insulating layer GI. The gate electrode GE and the second power conductive layer PL2b may be disposed on a same layer. For example, the gate electrode GE and the second power conductive layer PL2b may be simultaneously formed in a same process, but the disclosure is not necessarily limited thereto. The gate electrode GE may be disposed to overlap the semiconductor pattern SCP in the third direction (Z-axis direction) on the gate insulating layer GI. The second power conductive layer PL2b may be disposed to overlap the first power conductive layer PL2a in the third direction (Z-axis direction) on the gate insulating layer GI. The second power conductive layer PL2b may constitute the second power supply line PL2 described with reference to FIG. 4 or the like together with the first power conductive layer PL2a.

The gate electrode GE and the second power conductive layer PL2b may include a single layer or multiple layers including molybdenum (Mo), copper (Cu), aluminum (Al), chromium (Cr), gold (Au), titanium (Ti), and nickel (Ni), neodymium (Nd), indium (In), tin (Sn), and oxides or alloys thereof.

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. The interlayer insulating layer ILD may be disposed between the second power conductive layer PL2b and the third power conductive layer PL2c.

The interlayer insulating layer ILD may include a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The first and second transistor electrodes TE1 and TE2 of the transistor M and the third power conductive layer PL2c may be disposed on the interlayer insulating layer ILD. The first and second transistor electrodes TE1 and TE2 and the third power conductive layer PL2c may be disposed on a same layer. For example, the first and second transistor electrodes TE1 and TE2 and the third power conductive layer PL2c may be simultaneously formed in a same process, but the disclosure is not necessarily limited thereto.

The first and second transistor electrodes TE1 and TE2 may be disposed to overlap the semiconductor pattern SCP in the third direction (Z-axis direction). The first and second transistor electrodes TE1 and TE2 may be electrically connected to the semiconductor pattern SCP. For example, the first transistor electrode TE1 may be electrically connected to the first region of the semiconductor pattern SCP through a contact hole passing through the interlayer insulating layer ILD. The first transistor electrode TE1 may be electrically connected to the lower conductive layer BML through a contact hole passing through the interlayer insulating layer ILD and the buffer layer BFL. The second transistor electrode TE2 may be electrically connected to the second region of the semiconductor pattern SCP through a contact hole passing through the interlayer insulating layer ILD. According to an embodiment, one of the first and second transistor electrodes TE1 and TE2 may be a source electrode, and the other thereof may be a drain electrode.

The third power conductive layer PL2c may be disposed to overlap the first power conductive layer PL2a and/or the second power conductive layer PL2b in the third direction (Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole passing through the interlayer insulating layer ILD and the buffer layer BFL. The third power conductive layer PL2c may be electrically connected to the second power conductive layer PL2b through a contact hole passing through the interlayer insulating layer ILD. The third power supply conductive layer PL2c may constitute the second power supply line PL2 described with reference to FIG. 4 or the like together with the first power supply conductive layer PL2a and/or the second power supply conductive layer PL2b.

The first and second transistor electrodes TE1 and TE2 and the third power conductive layer PL2c may include a single layer or multiple layers including molybdenum (Mo), copper (Cu), aluminum (Al), chromium (Cr), gold (Au), titanium (Ti), and nickel (Ni), neodymium (Nd), indium (In), tin (Sn), and oxides or alloys thereof.

A passivation layer PSV may be disposed on the first and second transistor electrodes TE1 and TE2 and the third power supply conductive layer PL2c. The passivation layer PSV may include a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

A via layer VIA may be disposed on the passivation layer PSV. The via layer VIA may include an organic material so as to planarize the lower step. For example, the via layer VIA may include an organic material such as an acrylic resin, an epoxy resin, a phenolic resin, a polyamide resin, a polyimide resin, a polyester resin. (polyester resin), a polyphenylenesulfide resin, or benzocyclobutene (BCB). However, the disclosure is not necessarily limited thereto. The via layer VIA may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

First bank patterns BNP1 may be disposed on the via layer VIA. The first bank patterns BNP1 may have various shapes according to embodiments. In an embodiment, the first bank patterns BNP1 may have a shape protruding from the base layer BSL in the third direction (Z-axis direction). The first bank patterns BNP1 may be formed to have an inclined surface inclined at an angle with respect to the base layer BSL. However, the disclosure is not necessarily limited thereto, and the first bank patterns BNP1 may have sidewalls having a curved surface or a stepped shape. For example, the first bank patterns BNP1 may have a cross-section having a semi-circular or semi-elliptical shape.

The electrodes and insulating layers disposed on the first bank patterns BNP1 may have a shape corresponding to the first bank patterns BNP1. For example, the electrodes ALE disposed on the first bank patterns BNP1 may include an inclined surface or a curved surface having a shape corresponding to the shape of the first bank patterns BNP1. Therefore, the first bank patterns BNP1 may function as a reflection member that guides the light emitted from the light emitting elements LD in the front direction of the pixel PXL, for example, in the third direction (Z-axis direction) together with the electrodes ALE provided thereon, thereby improving the light output efficiency of the display panel PNL.

The first bank patterns BNP1 may include at least one organic material and/or at least one inorganic material. For example, the first bank patterns BNP1 may include an organic material such as an acrylic resin, an epoxy resin, a phenolic resin, a polyamide resin, a polyimide resin, a polyester resin. (polyester resin), a polyphenylenesulfide resin, or benzocyclobutene (BCB). However, the disclosure is not necessarily limited thereto. The first bank patterns BNP1 may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The electrodes ALE may be disposed on the via layer VIA and the first bank patterns BNP1. The electrodes ALE may be disposed to be apart from each other in the pixel PXL. The electrodes ALE may be disposed on a same layer. For example, the electrodes ALE may be simultaneously formed in a same process, but the disclosure is not necessarily limited thereto.

The electrodes ALE may receive an alignment signal in an alignment step of the light emitting elements LD. Therefore, an electric field is formed between the electrodes ALE, so that the light emitting elements LD provided to each of the pixels PXL may be aligned between the electrodes ALE.

The electrodes ALE may include at least one conductive material. For example, the electrodes ALE may include at least one conductive material selected from at least of various metal materials such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), alloys including the same, a conductive oxide such as indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and a conductive polymers such as PEDOT, but the disclosure is not necessarily limited thereto.

The first electrode ALE1 may be electrically connected to the first transistor electrode TE1 of the transistor M through a contact hole passing through the via layer VIA and the passivation layer PSV. The third electrode ALE3 may be electrically connected to the third power conductive layer PL2c through a contact hole passing through the via layer VIA and the passivation layer PSV.

A first insulating layer INS1 may be disposed on the electrodes ALE. The first insulating layer INS1 may include a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

Second bank patterns BNP2 may be disposed on the first insulating layer INS1. The second bank patterns BNP2 may form a dam structure that partitions the emission area to which the light emitting elements LD are to be supplied in the step of supplying the light emitting elements LD to each of the pixels PXL. For example, a desired type and/or amount of light emitting element ink may be supplied to the regions partitioned by the second bank patterns BNP2.

The second bank patterns BNP2 may include an organic material such as an acrylic resin, an epoxy resin, a phenolic resin, a polyamide resin, a polyimide resin, a polyester resin. (polyester resin), a polyphenylenesulfide resin, or benzocyclobutene (BCB). However, the disclosure is not necessarily limited thereto. The second bank patterns BNP2 may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

In an embodiment, the second bank patterns BNP2 may include at least one light blocking and/or reflective material. Therefore, light leakage between the adjacent pixels PXL may be prevented. For example, the second bank patterns BNP2 may include at least one black matrix material and/or at least one color filter material. For example, the second bank patterns BNP2 may include a black opaque pattern that blocks light transmission. In an embodiment, a reflective layer (not illustrated) may be formed on the surface (for example, sidewall) of the second bank patterns BNP2 so as to increase the optical efficiency of each pixel PXL.

The light emitting elements LD may be disposed on the first insulating layer INS1. The light emitting elements LD may be disposed between the electrodes ALE on the first insulating layer INS1. The light emitting elements LD may be prepared in a dispersed form in the light emitting element ink, and may be supplied to each of the pixels PXL through an inkjet printing method or the like within the spirit and the scope of the disclosure. For example, the light emitting elements LD may be dispersed in a volatile solvent and provided to each of the pixels PXL. In case that an alignment signal is supplied to the electrodes ALE, an electric field is formed between the electrodes ALE, so that the light emitting elements LD may be aligned between the electrodes ALE. After the light emitting elements LD are aligned, the light emitting elements LD may be stably arranged or disposed between the electrodes ALE by evaporating or removing the solvent in other ways.

A second insulating layer INS2 may be disposed on the light emitting elements LD. For example, the second insulating layer INS2 may be partially provided on the light emitting elements LD and expose the first and second ends EP1 and EP2 of the light emitting elements LD. In case that the second insulating layer INS2 is formed on the light emitting elements LD after the alignment of the light emitting elements LD is completed, it is possible to prevent the light emitting elements LD from being separated from the aligned positions.

The second insulating layer INS2 may include a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The connection electrodes ELT may be disposed on the first and second ends EP1 and EP2 of the light emitting elements LD exposed by the second insulating layer INS2. The first connection electrode ELT1 may be disposed on or directly disposed on the first ends EP1 of the first light emitting elements LD1 and may be in contact with the first ends EP1 of the first light emitting elements LD1.

The second connection electrode ELT2 may be disposed on or directly disposed on the second ends EP2 of the first light emitting elements LD1 and may be in contact with the second ends EP2 of the first light emitting elements LD1. The second connection electrode ELT2 may be disposed on or directly disposed on the first ends EP1 of the second light emitting elements LD2 and may be in contact with the first ends EP1 of the second light emitting elements LD2. For example, the second connection electrode ELT2 may electrically connect the second ends EP2 of the first light emitting elements LD1 and the first ends EP1 of the second light emitting elements LD2.

Similarly, the third connection electrode ELT3 may be disposed on or directly disposed on the second ends EP2 of the second light emitting elements LD2 and may be in contact with the second ends EP2 of the second light emitting elements LD2. The third connection electrode ELT3 may be disposed on or directly disposed on the first ends EP1 of the third light emitting elements LD3 and may be in contact with the first ends EP1 of the third light emitting elements LD3. For example, the third connection electrode ELT3 may electrically connect the second ends EP2 of the second light emitting elements LD2 and the first ends EP1 of the third light emitting elements LD3.

Similarly, the fourth connection electrode ELT4 may be disposed on or directly disposed on the second ends EP2 of the third light emitting elements LD3 and may be in contact with the second ends EP2 of the third light emitting elements LD3. The fourth connection electrode ELT4 may be disposed on or directly disposed on the first ends EP1 of the fourth light emitting elements LD4 and may be in contact with the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4.

Similarly, the fifth connection electrode ELT5 may be disposed on or directly disposed on the second ends EP2 of the fourth light emitting elements LD4 and may be in contact with the second ends EP2 of the fourth light emitting elements LD4.

In an embodiment, some or a number of connection electrodes ELT may be disposed on a same layer. For example, the first connection electrode ELT1, the third connection electrode ELT3, and the fifth connection electrode ELT5 may be disposed on a same layer. The second connection electrode ELT2 and the fourth connection electrode ELT4 may be disposed on a same layer. For example, the first connection electrode ELT1, the third connection electrode ELT3, and the fifth connection electrode ELT5 may be disposed on the second insulating layer INS2. A third insulating layer INS3 may be disposed on the first connection electrode ELT1, the third connection electrode ELT3, and the fifth connection electrode ELT5. The second connection electrode ELT2 and the fourth connection electrode ELT4 may be disposed on the third insulating layer INS3.

The third insulating layer INS3 may expose the second ends EP2 of the light emitting elements LD. The connection electrodes ELT may be formed on the second ends EP2 of the light emitting elements LD exposed by the third insulating layer INS3.

As such, in case that the third insulating layer INS3 is disposed between the connection electrodes ELT including different conductive layers, the connection electrodes ELT may be stably separated by the third insulating layer INS3, thereby securing electrical stability between the first and second ends EP1 and EP2 of the light emitting elements LD.

The connection electrodes ELT may include various transparent conductive materials. For example, the connection electrodes ELT may include at least one of various transparent conductive materials, including indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and may be implemented to be substantially transparent or translucent to satisfy a light transmittance. Therefore, light emitted from the first and second ends EP1 and EP2 of the light emitting elements LD may pass through the connection electrodes ELT and may be emitted to the outside of the display panel PNL.

The third insulating layer INS3 may include a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

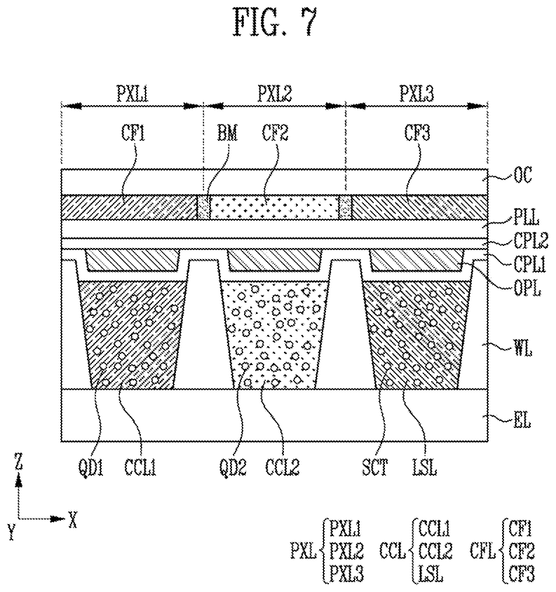

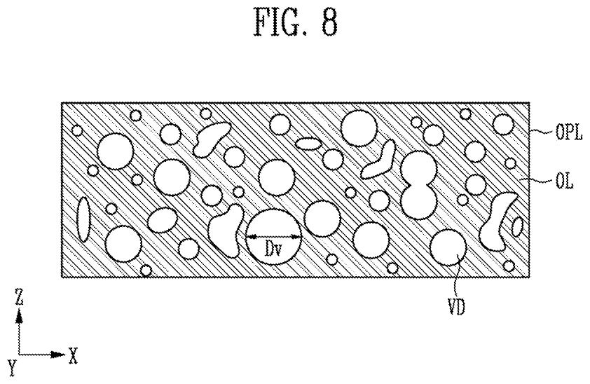

FIG. 7 is a schematic cross-sectional view illustrating the first to third pixels according to an embodiment. FIG. 8 is a schematic cross-sectional view illustrating the optical layer of FIG. 7.

FIG. 7 illustrates a partition wall WL, a color conversion layer CCL, an optical layer OPL, and/or a color filter layer CFL provided on the light emitting element layer EL of the pixel PXL described with reference to FIG. 6.

Referring to FIG. 7, the partition wall WL (or bank) may be disposed on the light emitting element layer EL of the first to third pixels PXL1, PXL2, and PXL3. For example, the partition wall WL may be disposed between the first to third pixels PXL1, PXL2, and PXL3, or the boundary therebetween, and may include an opening overlapping each of the first to third pixels PXL1, PXL2, and PXL3. The opening of the partition wall WL may provide a space in which the color conversion layer CCL and/or the optical layer OPL can be provided.

The partition wall WL may include an organic material such as an acrylic resin, an epoxy resin, a phenolic resin, a polyamide resin, a polyimide resin, a polyester resin. (polyester resin), a polyphenylenesulfide resin, or benzocyclobutene (BCB). However, the disclosure is not necessarily limited thereto. The partition wall WL may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

In an embodiment, the partition wall WL may include at least one light blocking and/or reflective material. Therefore, light leakage between the adjacent pixels PXL may be prevented. For example, the partition wall WL may include at least one black matrix material and/or at least one color filter material. For example, the partition wall WL may include a black opaque pattern that blocks light transmission. In an embodiment, a reflective layer (not illustrated) may be formed on the surface (for example, sidewall) of the partition wall WL so as to increase the optical efficiency of each pixel PXL.

The color conversion layer CCL may be disposed on the light emitting element layer EL including the light emitting elements LD within the opening of the partition wall WL. The color conversion layer CCL may include a first color conversion layer CCL1 disposed in the first pixel PXL1, a second color conversion layer CCL2 disposed in the second pixel PXL2, and a scattering layer LSL disposed in the third pixel PXL3.

In an embodiment, the first to third pixels PXL1, PXL2, and PXL3 may include light emitting elements LD that emit light of a same color as each other. For example, the first to third pixels PXL1, PXL2, and PXL3 may include light emitting elements LD that emit light of the third color (or the blue color). A full-color image may be displayed by disposing the color conversion layer CCL including color conversion particles on the first to third pixels PXL1, PXL2, and PXL3, respectively.

The first color conversion layer CCL1 may include first color conversion particles that convert light of the third color emitted from the light emitting element LD into light of the first color. For example, the first color conversion layer CCL1 may include first quantum dots QD1 dispersed in a matrix material such as a base resin.

In an embodiment, in case that the light emitting element LD is a blue light emitting element emitting blue light and the first pixel PXL1 is a red pixel, the first color conversion layer CCL1 may include a first quantum dot QD1 that converts blue light emitted from the blue light emitting element into red light. The first quantum dot QD1 may absorb blue light and shift a wavelength according to an energy transition to emit red light. As an example, in case that the first pixel PXL1 is a pixel of a different color, the first color conversion layer CCL1 may include a first quantum dot QD1 corresponding to the color of the first pixel PXL1.

The second color conversion layer CCL2 may include second color conversion particles that convert light of the third color emitted from the light emitting element LD into light of the second color. For example, the second color conversion layer CCL2 may include second quantum dots QD2 dispersed in a matrix material such as a base resin.

In an embodiment, in case that the light emitting element LD is a blue light emitting element emitting blue light and the second pixel PXL2 is a green pixel, the second color conversion layer CCL2 may include a second quantum dot QD2 that converts blue light emitted from the blue light emitting element into green light. The second quantum dot QD2 may absorb blue light and shift a wavelength according to an energy transition to emit green light. By way of an example, in case that the second pixel PXL2 is a pixel of a different color, the second color conversion layer CCL2 may include a second quantum dot QD2 corresponding to the color of the second pixel PXL2.

In an embodiment, blue light having a relatively short wavelength in the visible light band is incident on the first quantum dot QD1 and the second quantum dot QD2 to increase absorption coefficients of the first quantum dot QD1 and the second quantum dot QD2. Therefore, the light efficiency finally emitted from the first pixel PXL1 and the second pixel PXL2 may be improved, and excellent color reproducibility may be secured. The light emitting unit EMU of the first to third pixels PXL1, PXL2, and PXL3 is formed by using the light emitting elements LD (for example, blue light emitting elements) of a same color, thereby increasing the manufacturing efficiency of the display device.

The scattering layer LSL may be provided to efficiently use the light of the third color (or blue color) emitted from the light emitting element LD. For example, in case that the light emitting element LD is a blue light emitting element emitting blue light and the third pixel PXL3 is a blue pixel, the scattering layer LSL may include at least one type of scatterer SCT in order to efficiently use the light emitted from the light emitting element LD.

For example, the scattering layer LSL may include scatterers SCT dispersed in a matrix material such as a base resin. For example, the scattering layer LSL may include a scatterer SCT such as TiO₂, Al₂O₃, SiO₂, ZnO, ZrO₂, BaTiO₃, Ta₂O₅, Ti₃O₅, ITO, IZO, ATO, Nb₂O₃, SnO, and/or MgO. However, the constituent material of the scatterer SCT is not limited thereto. As an example, the scatterer SCT is not disposed only in the third pixel PXL3 and may be selectively included in the first color conversion layer CCL1 or the second color conversion layer CCL2. In an embodiment, the scatterer SCT may be omitted to provide the scattering layer LSL including a transparent polymer.

A first capping layer CPL1 may be disposed on the color conversion layer CCL. The first capping layer CPL1 may be provided over the first to third pixels PXL1, PXL2, and PXL3. The first capping layer CPL1 may cover or overlap the color conversion layer CCL. The first capping layer CPL1 may prevent impurities such as moisture or air from penetrating from the outside to damage or contaminate the color conversion layer CCL.

The first capping layer CPL1 is an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

The optical layer OPL may be disposed on the first capping layer CPL1. The optical layer OPL may improve light extraction efficiency by recycling light provided from the color conversion layer CCL by total reflection. The optical layer OPL may have a relatively low refractive index compared to the color conversion layer CCL. For example, the refractive index of the color conversion layer CCL may be in a range of about 1.6 to about 2.0, and the refractive index of the optical layer OPL may be in a range of about 1.10 to about 1.25. The refractive index of the optical layer OPL may be in a range of about 1.10 to about 1.12. In order to form the optical layer OPL having such an ultra-low refractive index, the optical layer OPL may include an organic layer OL surrounding voids VD. The optical layer will be described in detail with reference to FIG. 8.

Referring to FIG. 8, the voids VD of the optical layer OPL may be surrounded by or directly surrounded by the organic layer OL. The organic layer OL may include an organic material such as a silicon resin, an acrylic resin, an epoxy resin, a phenolic resin, a polyurethane resin, a polyamide resin, a polyimide resin, a polyester resin, a polyphenylenesulfide resin, or benzocyclobutene (BCB). For example, the organic layer OL may control the reaction and crosslinking degree by controlling the number of functional groups of the silicon resin, but the disclosure is not necessarily limited thereto. As an example, the organic layer OL may include an organic substituent having an organically modified silicate composition. For example, the organic layer OL may be formed by polymerizing R1xSi(OR2)4-x and R3ySi(OR4)4-y. R1 is an alkyl group having 1 to 10 carbon atoms, an aryl group having 6 to 10 carbon atoms, or an alkenyl group having 3 to 10 carbon atoms, R2 is an alkyl group having 1 to 6 carbon atoms, R3 is a fluoroalkyl group having 1 to 12 carbon atoms, and R4 may be an alkyl group having 1 to 6 carbon atoms. As an example the organic layer OL may include silsesquioxane (hydrogen silsesquioxane, alkyl silsesquioxane, aryl silsesquioxane, for example). As an example, the organic layer OL may include a polymer substituted with fluorine (F), but the disclosure is not limited thereto.

The void VD of the optical layer OPL may be a space (or cavity or aperture) in the organic layer OL while the void-forming material is volatilized by heat treatment. The optical layer OPL may not include a separate shell unlike hollow particles generally included in the low refractive index optical layer, for example, hollow silica by using the void VD. Therefore, the optical layer OPL having an ultra-low refractive index compared to hollow silica, whose refractive index is increased by the SiO₂ shell, may be formed. Since the optical layer OPL can be formed without expensive hollow particles, the cost can be reduced.

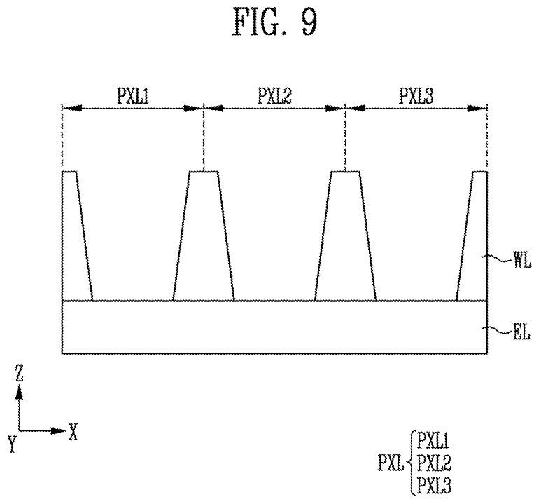

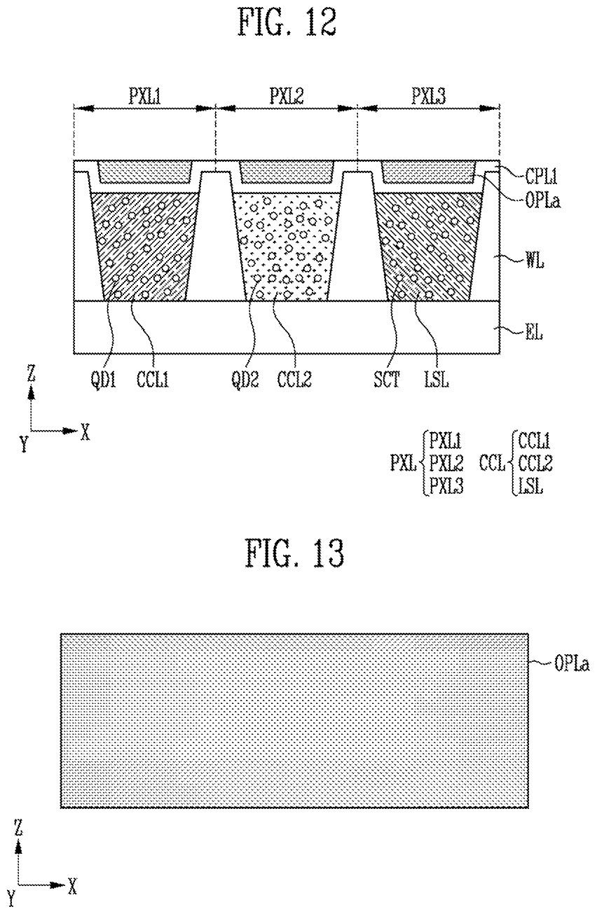

In the process in which the void-forming material is volatilized, the voids VD may be formed in various shapes and sizes. For example, each of the voids VD may be formed in various shapes such as circular, oval, and/or irregular shapes. The diameters Dv of the voids VD may be different from each other. For example, the diameters Dv of the voids VD may be in a range of about 2 nm to about 150 nm, but the disclosure is not necessarily limited thereto. In the process in which the void-forming material is volatilized, some or a number of voids VD may be formed in a shape connected to each other. A detailed description of the process of forming the voids VD of the optical layer OPL will be described below with reference to FIGS. 9 to 15.

As an example, in the process of forming the voids VD of the optical layer OPL, the crack margin decreases due to the difference in shrinkage between the matrix and the void-forming material, and cracks may occur in case that the thickness of the optical layer OPL is partially thickened due to the lower step. In order to prevent defects due to the reduction in the crack margin, the optical layer OPL may be provided in each of the first to third pixels PXL1, PXL2, and PXL3 to have a constant thickness. For example, as illustrated in FIG. 7, the optical layer OPL may be disposed in the opening of the partition wall WL. For example, the optical layer OPL of each of the first to third pixels PXL1, PXL2, and PXL3 may be separated from each other by the partition wall WL. It is possible to prevent defects due to the reduction in the crack margin by forming the optical layer OPL to a constant thickness without the influence of the lower step. For example, in order to prevent cracks from occurring, the optical layer OPL may be formed to have a thickness in a range of about 0.2 μm to about 3.0 μm. For example, in order to prevent cracks from occurring, the optical layer OPL may be formed to have a thickness in a range of about 0.3 μm to about 2.0 μm.

The optical layer OPL may be disposed on the color conversion layer CCL in the opening of the partition wall WL. For example, the optical layer OPL of the first pixel PXL1 may be disposed on the first color conversion layer CCL1 in the opening of the partition wall WL, the optical layer OPL of the second pixel PXL2 may be disposed on the second color conversion layer CCL2 in the opening of the partition wall WL, and the optical layer OPL of the third pixel PXL3 may be disposed on the scattering layer LSL in the opening of the partition wall WL.

A second capping layer CPL2 may be disposed on the optical layer OPL. The second capping layer CPL2 may be provided over the first to third pixels PXL1, PXL2, and PXL3. The second capping layer CPL2 may cover or overlap the optical layer OPL. The second capping layer CPL2 may prevent impurities such as moisture or air from penetrating from the outside to damage or contaminate the optical layer OPL.

In an embodiment, as the optical layer OPL is disposed in the opening of the partition wall WL and is separated by the partition wall WL, the second capping layer CPL2 and the first capping layer CPL1 may be in contact with each other on the partition wall WL.

The second capping layer CPL2 is an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}).

A planarization layer PLL may be disposed on the second capping layer CPL2. The planarization layer PLL may be provided over the first to third pixels PXL1, PXL2, and PXL3.

The planarization layer PLL may include an organic material such as an acrylic resin, an epoxy resin, a phenolic resin, a polyamide resin, a polyimide resin, a polyester resin. (polyester resin), a polyphenylenesulfide resin, or benzocyclobutene (BCB). However, the disclosure is not necessarily limited thereto. The planarization layer PLL may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The color filter layer CFL may be disposed on the planarization layer PLL. The color filter layer CFL may include color filters CF1, CF2, and CF3 matching the color of each pixel PXL. The color filters CF1, CF2, and CF3 corresponding to the colors of the first to third pixels PXL1, PXL2, and PXL3 may be disposed to display a full-color image.

The color filter layer CFL may include a first color filter CF1 disposed in the first pixel PXL1 to selectively transmit light emitted from the first pixel PXL1, a second color filter CF2 disposed in the second pixel PXL2 to selectively transmit light emitted from the second pixel PXL2, and a third color filter CF3 disposed in the third pixel PXL3 to selectively transmit light emitted from the third pixel PXL3.

In an embodiment, the first color filter CF1, the second color filter CF2, and the third color filter CF3 may be a red color filter, a green color filter, and a blue color filter, respectively. However, the disclosure is not necessarily limited thereto. Hereinafter, any color filter among the first color filter CF1, the second color filter CF2, and the third color filter CF3 may be referred to as a “color filter CF”, and two or more types of color filters may be referred to as “color filters CF”.

The first color filter CF1 may overlap the light emitting element layer EL (or the light emitting element LD) and the first color conversion layer CCL1 of the first pixel PXL1 in the third direction (Z-axis direction). The first color filter CF1 may include a color filter material that selectively transmits light of the first color (or red color). For example, in case that the first pixel PXL1 is a red pixel, the first color filter CF1 may include a red color filter material.

The second color filter CF2 may overlap the light emitting element layer EL (or the light emitting element LD) and the second color conversion layer CCL2 of the second pixel PXL2 in the third direction (Z-axis direction). The second color filter CF2 may include a color filter material that selectively transmits light of the second color (or green color). For example, in case that the second pixel PXL2 is a green pixel, the second color filter CF2 may include a green color filter material.

The third color filter CF3 may overlap the light emitting element layer EL (or the light emitting element LD) and the scattering layer LSL of the third pixel PXL3 in the third direction (Z-axis direction). The third color filter CF3 may include a color filter material that selectively transmits light of a third color (or blue color). For example, in case that the third pixel PXL3 is a blue pixel, the third color filter CF3 may include a blue color filter material.

In an embodiment, a light blocking layer BM may be further disposed between the first to third color filters CF1, CF2, and CF3. As such, in case that the light blocking layer BM is formed between the first to third color filters CF1, CF2, and CF3, color mixing defects recognized from the front or side surfaces of the display device may be prevented. A material of the light blocking layer BM is not particularly limited, and may include various light blocking materials. For example, the light blocking layer BM may be implemented by stacking the first to third color filters CF1, CF2, and CF3 on each other.

An overcoat layer OC may be disposed on the color filter layer CFL. The overcoat layer OC may be provided over the first to third pixels PXL1, PXL2, and PXL3. The overcoat layer OC may cover or overlap a lower member including the color filter layer CFL. The overcoat layer OC may prevent moisture or air from penetrating into the above-described lower member. The overcoat layer OC may protect the above-described lower member from foreign material such as dust.

The overcoat layer OC may include an organic material such as a polyhedral oligomeric silsesquioxane (POSS) compound, an acrylic resin, an epoxy resin, a phenolic resin, a polyamide resin, a polyimide resin, a polyester resin, a polyphenylenesulfide resin, or a benzocyclobutene (BCB). However, the disclosure is not necessarily limited thereto, and the overcoat layer OC may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

According to the above-described embodiment, since the optical layer OPL having an ultra-low refractive index can be formed using the voids VD without an expensive low-refractive material, the cost can be reduced.

Subsequently, a method of manufacturing the display device according to an embodiment will be described.

FIGS. 9 to 15 are schematic cross-sectional views of step-by-step processes of a method of manufacturing a display device according to an embodiment. FIGS. 9 to 15 are schematic cross-sectional views for describing the method of manufacturing the display device of FIGS. 7 and 8. The elements substantially the same as those of FIGS. 7 and 8 are denoted by the same reference numerals, and detailed reference numerals are omitted.

Referring to FIG. 9, a partition wall WL (or bank) is formed on a light emitting element layer EL. The partition wall WL may be disposed between first to third pixels PXL1, PXL2, and PXL3, or the boundary therebetween, and may include an opening overlapping each of the first to third pixels PXL1, PXL2, and PXL3. The opening of the partition wall WL may overlap the light emitting element LD described with reference to FIG. 6. The opening of the partition wall WL may provide a space in which a color conversion layer CCL and/or an optical layer OPL can be provided in a subsequent process.

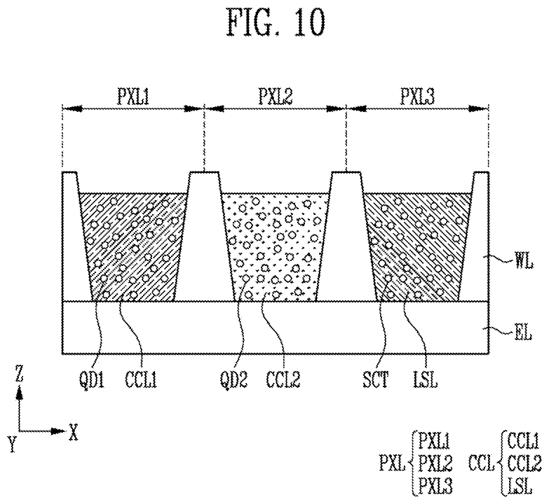

Referring to FIG. 10, the color conversion layer CCL is formed in the opening of the partition wall WL. The color conversion layer CCL may be disposed on the light emitting element layer EL including the light emitting elements LD within the opening of the partition wall WL. A first color conversion layer CCL1 may be provided in the first pixel PXL1, a second color conversion layer CCL2 may be provided in the second pixel PXL2, and a scattering layer LSL may be provided in the third pixel PXL3.

In an embodiment, in case that the light emitting element LD is a blue light emitting element emitting blue light and the first pixel PXL1 is a red pixel, the first color conversion layer CCL1 may include a first quantum dot QD1 that converts blue light emitted from the blue light emitting element into red light. The first quantum dot QD1 may absorb blue light and shift a wavelength according to an energy transition to emit red light. As an example, in case that the first pixel PXL1 is a pixel of a different color, the first color conversion layer CCL1 may include a first quantum dot QD1 corresponding to the color of the first pixel PXL1.

In an embodiment, in case that the light emitting element LD is a blue light emitting element emitting blue light and the second pixel PXL2 is a green pixel, the second color conversion layer CCL2 may include a second quantum dot QD2 that converts blue light emitted from the blue light emitting element into green light. The second quantum dot QD2 may absorb blue light and shift a wavelength according to an energy transition to emit green light. As an example, in case that the second pixel PXL2 is a pixel of a different color, the second color conversion layer CCL2 may include a second quantum dot QD2 corresponding to the color of the second pixel PXL2.

In an embodiment, blue light having a relatively short wavelength in the visible light band is incident on the first quantum dot QD1 and the second quantum dot QD2 to increase absorption coefficients of the first quantum dot QD1 and the second quantum dot QD2. Therefore, the light efficiency finally emitted from the first pixel PXL1 and the second pixel PXL2 may be improved, and excellent color reproducibility may be secured. The light emitting unit EMU of the first to third pixels PXL1, PXL2, and PXL3 is formed by using the light emitting elements LD (for example, blue light emitting elements) of a same color, thereby increasing the manufacturing efficiency of the display device as described above.

The scattering layer LSL may be provided to efficiently use the light of the third color (or blue color) emitted from the light emitting element LD. For example, in case that the light emitting element LD is a blue light emitting element emitting blue light and the third pixel PXL3 is a blue pixel, the scattering layer LSL may include at least one type of scatterer SCT in order to efficiently use the light emitted from the light emitting element LD.

For example, the scattering layer LSL may include scatterers SCT dispersed in a matrix material such as a base resin. As an example, the scattering layer LSL may include a scatterer SCT such as silica, but the material of the scatterer SCT is not limited thereto. As an example, the scatterer SCT is not disposed only in the third pixel PXL3 and may be selectively included in the first color conversion layer CCL1 or the second color conversion layer CCL2. In an embodiment, the scatterer SCT may be omitted to provide the scattering layer LSL including a transparent polymer.

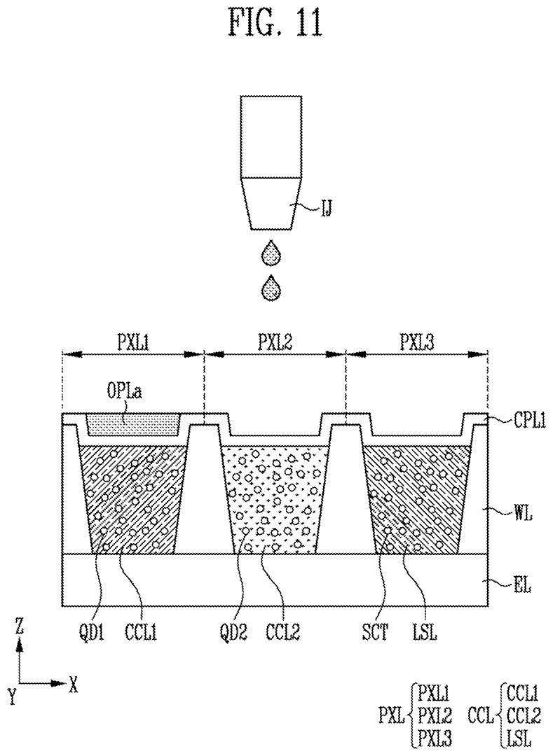

Referring to FIGS. 11 to 13, a first capping layer CPL1 is formed on the color conversion layer CCL, and an optical material layer OPLa is provided in each of the first to third pixels PXL1, PXL2, and PXL3.

The first capping layer CPL1 may be provided over the first to third pixels PXL1, PXL2, and PXL3. The first capping layer CPL1 may cover or overlap the color conversion layer CCL. As described above, the first capping layer CPL1 may prevent impurities such as moisture or air from penetrating from the outside to damage or contaminate the color conversion layer CCL.

The optical material layer OPLa may be disposed on the first capping layer CPL1 and/or the color conversion layer CCL in the opening of the partition wall WL.

The optical material layer OPLa may include a void-forming material mixed with a matrix including an organic material. The content of the void-forming material may be in a range of about 40 wt % to about 70 wt % based on the total weight of the optical material layer OPLa, but the disclosure is not necessarily limited thereto.

The matrix may include an organic material such as a silicon resin, an acrylic resin, an epoxy resin, a phenolic resin, a polyurethane resin, a polyamide resin, a polyimide resin, a polyester resin, a polyphenylenesulfide resin, or benzocyclobutene (BCB). For example, the matrix may control the reaction and crosslinking degree by controlling the number of functional groups of the silicon resin, but the disclosure is not necessarily limited thereto. As an example, the matrix may include an organic substituent having an organically modified silicate composition. For example, the matrix may be formed by polymerizing R1xSi(OR2)4-x and R3ySi(OR4)4-y. R1 is an alkyl group having 1 to 10 carbon atoms, an aryl group having 6 to 10 carbon atoms, or an alkenyl group having 3 to 10 carbon atoms, R2 is an alkyl group having 1 to 6 carbon atoms, R3 is a fluoroalkyl group having 1 to 12 carbon atoms, and R4 may be an alkyl group having 1 to 6 carbon atoms. As an example, the matrix may include silsesquioxane (hydrogen silsesquioxane, alkyl silsesquioxane, aryl silsesquioxane, for example). As an example, the matrix may include a polymer substituted with fluorine (F), but the disclosure is not necessarily limited thereto.

The molecular weight of the void-forming material may be in a range of about 100 to about 50,000. As an example, the molecular weight of the void-forming material may be in a range of about 1,000 to about 7,000, but the disclosure is not necessarily limited thereto. The void-forming material may include a monomer or a dimer, and may include cyclohexanol, dodecanol, glycidyl methacrylate, ethylene dimethacrylate, n-butanol, hydrocarbon (CHx-CHy), polyethylene oxide (PEO), polypropylene oxide (PPO), dendrimer, cyclodextrin, polyester, polystyrene, polyacrylate, polycarbonate, polyether, polyalkylene oxide, polycaprolactone, polyvalerolactone, polymethylmethaacrylate, and/or tetradecane However, the disclosure is not necessarily limited thereto, and the void-forming material may include various materials that forms voids by volatilization by heat treatment in a subsequent process. The void-forming material may exist separately from the matrix. As an example, the matrix and the void-forming material may form a bond between side chains.

The optical material layer OPLa may be provided by an inkjet printing method. For example, the optical material layer OPLa may be provided on the color conversion layer CCL by an inkjet printing apparatus IJ. The optical material layer OPLa is ink in a solution state, and may be discharged or sprayed onto the color conversion layer CCL through a nozzle of the inkjet printing apparatus IJ or the like within the spirit and the scope of the disclosure. In an embodiment, since the optical material layer OPLa does not use a low-refractive material such as hollow particles, inkjet ejection properties may be improved. For example, it is possible to prevent a phenomenon in which the nozzle of the inkjet printing apparatus IJ is clogged by hollow particles or a difference in the thickness of the optical material layer OPLa occurs due to poor discharge, thereby preventing a stain from being recognized.

The optical material layer OPLa may be selectively discharged or sprayed onto each of the first to third pixels PXL1, PXL2, and PXL3. As described above, in the case in which the optical material layer OPLa is selectively provided to each of the first to third pixels PXL1, PXL2, and PXL3, even if the crack margin is reduced due to the difference in shrinkage between the matrix and the void-forming material during the heat treatment of the optical material layer OPLa in the subsequent process, cracks can be prevented from occurring by forming the optical layer OPL to a thickness without the influence of the lower step. In an embodiment, the optical layer OPL may be formed to a thickness in a range of about 0.2 μm to about 3.0 μm so as to prevent cracks from occurring. For example, in order to prevent cracks from occurring, the optical layer OPL may be formed to have a thickness in a range of about 0.3 μm to about 2.0 μm.

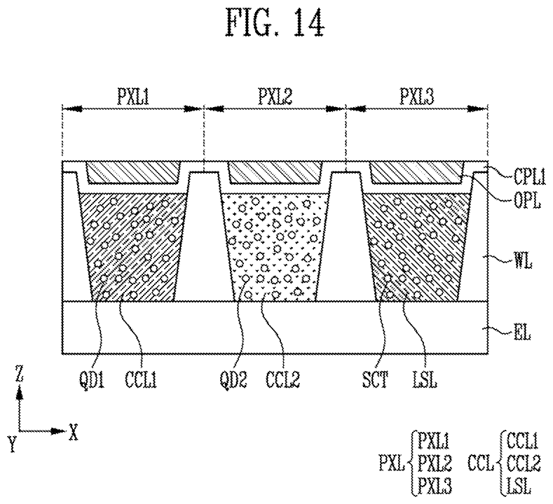

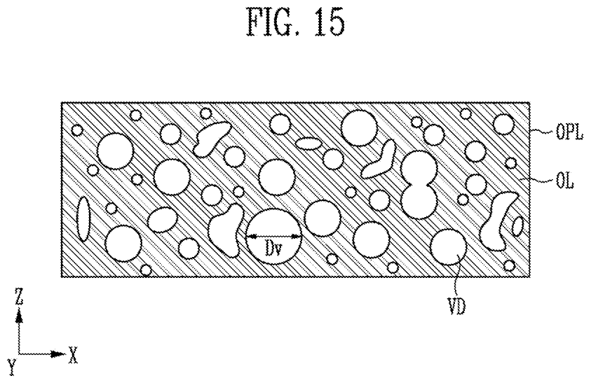

Referring to FIGS. 14 and 15, the optical material layer OPLa is heat-treated to form the optical layer OPL. During the heat treatment of the optical material layer OPLa, the void-forming material may be volatilized to form voids VD in the organic layer OL (or the matrix). As such, in case that the voids VD are formed in the organic layer OL, a separate shell is not included unlike the hollow silica included in the low refractive index optical layer, and thus, an ultra-low refractive index optical layer OPL can be formed. Since the optical layer OPL can be formed without expensive hollow particles, the cost can be reduced.

For example, in case that the content of the void-forming material is about 40 wt % based on the total weight of the optical material layer OPLa, the refractive index of the optical layer OPL may be about 1.25. In case that the content of the void-forming material is about 50 wt % based on the total weight of the optical material layer OPLa, the refractive index of the optical layer OPL may be about 1.21. In case that the content of the void-forming material is about 60 wt % based on the total weight of the optical material layer OPLa, the refractive index of the optical layer OPL may be about 1.16. In case that the content of the void-forming material is about 70 wt % based on the total weight of the optical material layer OPLa, the refractive index of the optical layer OPL may be about 1.12.

In the process in which the void-forming material is volatilized, the voids VD may be formed in various shapes and sizes. For example, each of the voids VD may be formed in various shapes such as circular, oval, and/or irregular shapes. The diameters Dv of the voids VD may be different from each other. For example, the diameters Dv of the voids VD may be in a range of about 2 nm to about 150 nm, but the disclosure is not necessarily limited thereto. In the process in which the void-forming material is volatilized, some or a number of voids VD may be formed in a shape connected to each other.

In order to prevent the lower color conversion layer CCL from being damaged by the heat treatment in the process of volatilizing the void-forming material, the heat treatment process may be performed at about 200° C. or less.

A second capping layer CPL2, a planarization layer PLL, a color filter layer CFL, and/or an overcoat layer OC are formed on the optical layer OPL to complete the display device illustrated in FIG. 7.

According to the above-described embodiment, the optical layer OPL may be formed by volatilizing the void-forming material to form the voids VD. For example, since expensive hollow particles are not used in the process of forming the optical layer OPL, inkjet discharge properties are improved, cost is reduced, and the optical layer OPL having an ultra-low refractive index can be formed. Even in case that the crack margin is reduced in the process of forming the voids VD, defects due to the reduction in the crack margin can be prevented by separating the optical layer OPL in each of the pixels PXL and forming the optical layer to a thickness.

According to an embodiment, the cost can be reduced because the optical layer having the ultra-low refractive index can be formed by using the voids without an expensive low-refractive material.

Even in case that the crack margin is reduced in the process of forming the voids, defects due to the reduction in the crack margin can be prevented by separating the optical layer in each of the pixels and forming the optical layer to a thickness.

Effects according to the embodiments are not limited by the above description presented above, and more various effects are incorporated in the specification.

It will be understood that those of ordinary skill in the art that the disclosure can be variously modified without departing from the features of the above description. Therefore, the description is to be considered in an illustrative sense rather than a restrictive sense. The scope of the disclosure is indicated in the claims in addition to the foregoing description, and all differences within the scope equivalent thereto should be construed as included within the disclosure.

What is claimed is:

1. A display device comprising:
pixels;
a bank including an opening overlapping each of the pixels in a plan view;
light emitting elements disposed in the pixels;
a color conversion layer disposed on the light emitting elements in the opening of the bank; and
an optical layer disposed on the color conversion layer in the opening of the bank,
wherein the optical layer includes an organic layer surrounding voids of the optical layer.

2. The display device of claim 1, wherein the optical layer has a refractive index of about 1.25 or less.

3. The display device of claim 1, wherein the optical layer has a thickness in a range of about 0.2 μm to about 3.0 μm.

4. The display device of claim 1, wherein the voids of the optical layer have different diameters.

5. The display device of claim 1, wherein each of the voids of the optical layer has a diameter in a range of about 2 nm to about 150 nm.

6. The display device of claim 1, wherein
the pixels include first pixels, second pixels, and third pixels, and
optical layers of the first pixels, the second pixels, and the third pixels are separated from each other.

7. The display device of claim 1, further comprising:
a first capping layer disposed between the color conversion layer and the optical layer.

8. The display device of claim 7, further comprising:
a second capping layer overlapping the optical layer in a plan view.

9. The display device of claim 8, wherein the second capping layer contacts the first capping layer on the bank.

10. The display device of claim 1, wherein the light emitting elements each include:
a first semiconductor layer;
a second semiconductor layer disposed on the first semiconductor layer; and
an active layer disposed between the first semiconductor layer and the second semiconductor layer.

11. A method of manufacturing a display device, the method comprising:
providing a bank including an opening overlapping light emitting elements of pixels in a plan view;
providing a color conversion layer in the opening of the bank;
providing an optical material layer including a void-forming material on the color conversion layer; and
performing heat treatment on the optical material layer to volatilize the void-forming material to form an optical layer.

12. The method of claim 11, further comprising:
volatilizing the void-forming material to form voids in the optical layer.

13. The method of claim 11, wherein the heat treatment is performed at about 200° C. or less.

14. The method of claim 11, wherein a content of the void-forming material is in a range of about 40 wt % to about 70 wt % based on a total weight of the optical material layer.

15. The method of claim 12, wherein the voids of the optical layer are formed to have different diameters.

16. The method of claim 12, wherein each of the voids of the optical layer is formed to have a diameter in a range of about 2 nm to about 150 nm.

17. The method of claim 11, wherein the optical layer is formed to have a thickness in a range of about 0.2 μm to about 3.0 μm.

18. The method of claim 11, wherein the optical material layer is disposed in the opening of the bank.

19. The method of claim 11, wherein
the pixels include first pixels, second pixels, and third pixels, and
the optical material layer is disposed separately in the first pixels, the second pixels, and the third pixels.

20. The method of claim 11, wherein the optical material layer is provided by inkjet printing.
